(19) United States
(12) Patent Application Publication
(10) Pub. No.: US 2024/0321571 A1
(43) Pub. Date: Sep. 26, 2024

(54) INSULATING FILM FORMING METHOD AND SUBSTRATE PROCESSING SYSTEM

(71) Applicant: Tokyo Electron Limited, Tokyo (JP)

(72) Inventors: Daisuke OBA, Nirasaki City (JP); Masafumi ISHIDA, Nirasaki City (JP); Nobuo MATSUKI, Nirasaki City (JP); Yoshinori MORISADA, Nirasaki City (JP)

(21) Appl. No.: 18/609,278

(22) Filed: Mar. 19, 2024

(30) Foreign Application Priority Data
Mar. 22, 2023 (JP) 2023-045031

(51) Int. Cl. H01L 21/02; C23C 16/46; C23C 16/50; C23C 16/52; C23C 16/56; H01J 37/32

(52) U.S. Cl. CPC H01L 21/02274; C23C 16/46; C23C 16/50; C23C 16/52; C23C 16/56; H01J 37/32449; H01J 37/32816; H01J 2237/3321; H01J 2237/3382; H01L 21/0234

(57) ABSTRACT

A method of forming an insulating film on a substrate having a recess, includes preparing the substrate inside a chamber of a processing apparatus, forming a flowable oligomer film on the substrate by supplying a processing gas containing a raw material gas and a diluent gas into the chamber and generating a flowable oligomer by plasma polymerization, controlling an interior of the chamber to have a pressure equal to or lower than a vapor pressure of the flowable oligomer to partially vaporize and remove the flowable oligomer film, and forming the insulating film in the recess by supplying energy to the substrate to cure the flowable oligomer.

### CROSS-REFERENCE TO RELATED APPLICATION

This application is based upon and claims the benefit of priority from Japanese Patent Application No. 2023-045031, filed on Mar. 22, 2023, the entire contents of which are incorporated herein by reference.

### TECHNICAL FIELD

The present disclosure relates to an insulating film forming method and a substrate processing system.

### BACKGROUND

A semiconductor device manufacturing process includes a process of embedding an insulating film into a fine three-dimensional structure on a substrate. Embedding such an insulating film includes a method of applying a flowable liquid by spin coating.

In addition, as a technique capable of obtaining better film quality, there is a method of embedding an insulating film by causing a flowable oligomer to be directly deposited and flow on a substrate by using flowable chemical vapor deposition (CVD).

For example, Patent Document 1 proposes a method of forming an insulating film in which a film of a flowable silanol compound is formed on a substrate by reacting an oxygen-containing organosilicon compound gas and a non-oxidizing hydrogen-containing gas with each other as film forming gases in a state in which at least the non-oxidizing hydrogen-containing gas is plasmatized, and then turning the silanol compound into an insulating film by annealing the substrate.

### PRIOR ART DOCUMENT

### Patent Document

Patent Document 1: International Publication No. WO 2021/010004

### SUMMARY

According to one embodiment of the present disclosure, there is provided a method of forming an insulating film on a substrate having a recess, includes preparing the substrate inside a chamber of a processing apparatus, forming a flowable oligomer film on the substrate by supplying a processing gas containing a raw material gas and a diluent gas into the chamber and generating a flowable oligomer by plasma polymerization, controlling an interior of the chamber to have a pressure equal to or lower than a vapor pressure of the flowable oligomer to partially vaporize and remove the flowable oligomer film, and forming the insulating film in the recess by supplying energy to the substrate to cure the flowable oligomer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an example of an insulating film forming method according to a first embodiment.

FIGS. 2A to 2D are schematic views illustrating an insulating film forming process according to the first embodiment.

FIG. 3 is a schematic view illustrating the insulating film forming process according to the first embodiment.

FIG. 4 is a schematic view illustrating a typical specific example of an insulating film forming method according to the first embodiment.

FIGS. 5A to 5C are views illustrating examples of experimental results regarding formed insulating films.

FIG. 6 is a flowchart illustrating an example of an insulating film forming method according to a second embodiment.

FIGS. 7A to 7F are schematic views illustrating an insulating film forming process according to the second embodiment.

FIG. 8 is a view illustrating each process and a time chart of an insulating film forming method according to Example 1.

FIG. 9 is a view illustrating each process and a time chart of an insulating film forming method according to Example 2.

FIG. 10 is a view illustrating each process and a time chart of an insulating film forming method according to Example 3.

FIG. 11 is a view illustrating each process and a time chart of an insulating film forming method according to Example 4.

FIG. 12 is a view illustrating each process and a time chart of an insulating film forming method according to Example 5.

FIG. 13 is a view illustrating each process and a time chart of an insulating film forming method according to Example 6.

FIG. 14 is a view illustrating each process and a time chart of an insulating film forming method according to Example 7.

FIGS. 15A to 15C are views illustrating examples of experimental results regarding formed insulating films.

FIG. 16 is a schematic configuration view illustrating an example of a substrate processing system that performs an insulating film forming method.

FIG. 17 is a cross-sectional view illustrating an example of a processing apparatus that performs generation and vaporization of a flowable oligomer in the substrate processing system of FIG. 16.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each of the drawings, the same components may be denoted by the same reference numerals, and redundant descriptions thereof may be omitted.

### [Method of Forming Insulating Film]

There is a method of causing a flowable film to be directly deposited and flow on a substrate by using flowable CVD to embed an insulating film in a recess on the substrate. In this case, since the flowable film is formed not only inside the recess but also on the top and sidewall portions of the recess, it may not be possible to embed the insulating film in a desired shape. Since it is not possible to embed the insulating film in a desired shape, for example, the film quality may not be improved sufficiently in the deep portion of the flowable film by annealing or a post-process may be required to remove the flowable film formed in unnecessary portions.

Therefore, in a method of forming an insulating film according to an embodiment described below, after a film forming process in which a flowable film polymerized by plasma CVD is deposited and flowed to form a film in a recess, a vaporization process is performed to vaporize and remove the flowable film formed on the top and sidewall portions of the recess. This makes it possible to embed an insulating film in a desired shape by using a flowable film. Hereinafter, a method of forming an insulating film according to a first embodiment and a method of forming an insulating film according to a second embodiment will be described in this order.

### First Embodiment

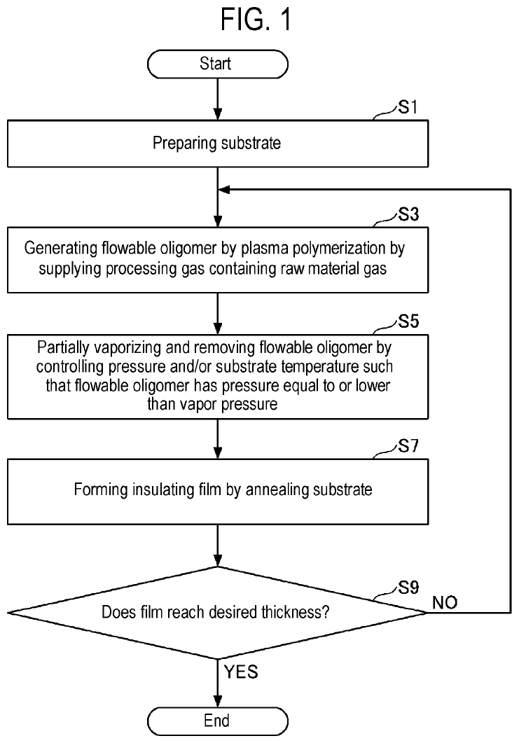

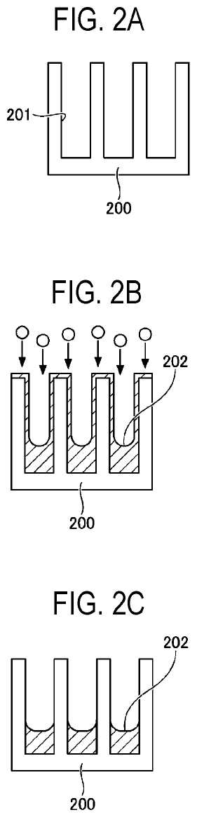

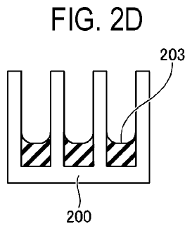

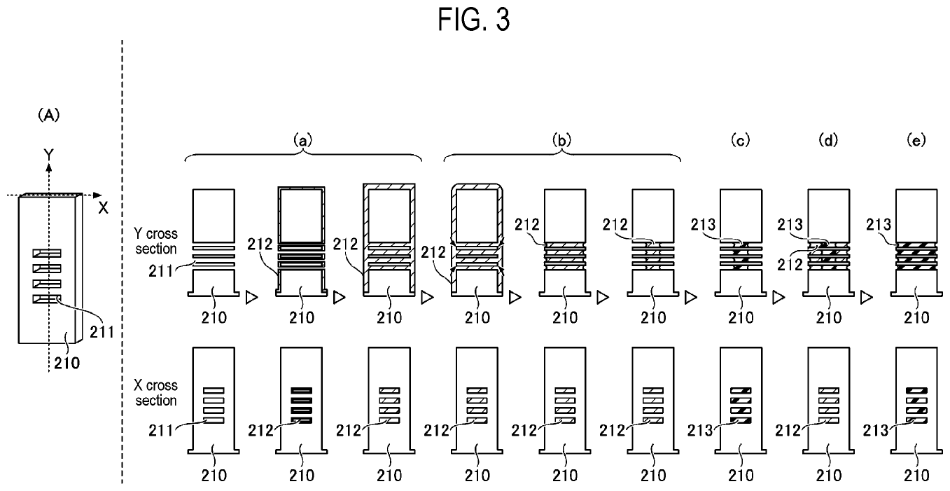

An insulating film forming method according to a first embodiment will be described with reference to FIGS. 1 to 3. FIG. 1 is a flowchart illustrating an example of an insulating film forming method according to the first embodiment. FIGS. 2A to 2D and 3 are schematic views illustrating an insulating film forming process according to the first embodiment.

The insulating film forming method according to the first embodiment includes preparing a substrate by carrying the substrate into a chamber of a processing apparatus, which will be described later, and placing the substrate on a stage in step S1. Next, in step S3, a processing gas containing a raw material gas is supplied into the chamber, and a flowable oligomer is generated by plasma polymerization to form a film on the substrate. A precursor gas and a non-oxidizing hydrogen-containing gas as a raw material gas are reacted, in a state in which at least the non-oxidizing hydrogen-containing gas is plasmatized, to generate a flowable oligomer and to form a film on the substrate.

Next, in step S5, a pressure inside the chamber is controlled to be equal to or lower than a vapor pressure of the flowable oligomer, so that the flowable oligomer formed into a film is partially vaporized and removed. Next, in step S7, energy such as heat or plasma is supplied to the substrate to cure the flowable oligomer and to form an insulating film in the recess on the substrate. In step S9, it is determined whether the insulating film has reached a predetermined thickness, and the processes of steps S3 to S7 are repeated until the insulating film reaches the predetermined thickness, and when the insulating film reaches the predetermined thickness, the process is terminated. Each of the processes of steps S3 to S7 will be described in detail below.

### (Step S1: Substrate Preparation Process)

Although the substrate to be prepared is not particularly limited, a semiconductor substrate (semiconductor wafer) such as silicon is exemplified. As the substrate, a substrate having a fine three-dimensional structure on the surface thereof may be used. The fine three-dimensional structure includes a recess such as a trench and a hole.

### (Step S3: Flowable Film Forming Process)

A processing gas used to form a flowable film includes a raw material gas that constitutes a precursor gas. As the raw material gas, a silicon (Si)-containing gas or a boron (B)-containing gas may be used. The silicon-containing gas may be a gas containing Si—O bonds or a gas containing Si—N bonds.

Examples of gases containing Si—O bonds include alkoxysilane compounds (alkoxysilane monomers). Examples of alkoxysilane compounds include (R1)ₐSi(—O—R2)₄ₐ (where R1 may be any of —CH₃, —C₂H₅, —C₃H₇, —C₂H₃, and —C₂H, and R2 may be any of —CH₃ and —C₂H₅ where a is 0, 1, 2, or 3). Specifically, examples of gases containing Si—O bonds include tetramethoxysilane (TMOS; Si(OCH₃)₄), methyltrimethoxysilane (MTMOS; Si(OCH₃)₃CH₃), and tetraethoxysilane (TEOS; Si(OC₂H₅)₄), methyltriethoxysilane (MTEOS; Si(OC₂H₅)₃CH₃), dimethyldimethoxysilane (DMDMOS; Si(OCH₃)₂(CH₃)₂), triethoxysilane (SiH(OC₂H₅)₃), trimethoxysilane (SiH (OCH₃)₃), trimethoxy disiloxane (Si(OCH₃)₃OSi(OCH₃)₃), and the like. These compounds may be used alone or in combination of two or more.

Examples of gases containing Si—N bonds include bis(tert-butylamino)silane (BTBAS), bis(tert-butylamino)methylsilane (BTBAS-MS), bis(ethylmethylamino)silane (BEMAS), tri-dimethyl-aminosilane (3DMAS), methyl-tri-dimethyl-aminosilane (3DMAMS), hexamethylcyclotrisilazane (HMCTSilazane), and the like. These compounds may be used alone or in combination of two or more.

Examples of boron (B)-containing gases include diborane (B₂H₆), borazine, triethylborane (TEB), triethylamine borane (BTEA), tri(dimethylamino)borane (TDMAB), tri(ethylmethylamino)borane (TEMAB), trimethylborazine (TMB), and the like. These compounds may be used alone or in combination of two or more.

In step S3, a flowable oligomer is generated by plasma polymerization by using the above-mentioned raw material gases, and flowable CVD is performed. The plasma polymerization may be performed by adding a non-oxidizing hydrogen-containing gas to the above-mentioned raw material gases to generate plasma. Examples of the non-oxidizing hydrogen-containing gases include H₂ gas, NH₃ gas, and SiH₄ gas, and these may be used alone or in combination of two or more.

The processing gas may include a diluent gas. The diluent gas is at least one selected from inert gases such as He, Ne, Ar, and Kr, H₂ gas, a halogen gas, or a hydrocarbon gas.

As plasma for the plasma polymerization, a plasma containing an inert gas, such as He, Ne, Ar, Kr, or N₂, or plasma containing an inert gas and hydrogen, such as Ar/H₂ plasma, may be used. In addition, the method of generating plasma is not particularly limited, and various methods such as a capacitively coupled plasma (CCP) generation method, an inductively coupled plasma (ICP) generation method, and a microwave plasma (MWP) generation method may be used. Among these, CCP is preferred. Furthermore, during the plasma polymerization, the raw material gas may or may not be plasmatized. When the raw material gas is not plasmatized, a remote plasma system which introduces plasma containing a hydrogen-containing gas into the chamber, may be used, while introducing the raw material gas into the chamber.

Due to the above-described reaction between the raw material gas and the non-oxidizing hydrogen-containing gas, some of the alkyl groups and alkoxy groups of the raw material gas are separated and polymerized to generate a flowable oligomer, and the flowable oligomer is formed into a film on the substrate. The film formation at this time is performed as illustrated in FIGS. 2A to 2D. That is, a substrate 200 with fine recesses 201 formed on its surface as illustrated in FIG. 2A is prepared, and a flowable oligomer 202 generated by the plasma polymerization flows into the recesses 201 due to surface tension, as illustrated in FIG. 2B.

The term “oligomer” refers to a polymer (multimer) in which a relatively small number (up to several ten molecules) of monomers are bonded. In the present embodiment, examples of flowable oligomers include those containing any one of SiOH, SiNH, SiCOH, SiCNH, SiCH, BNH, BCNH, SiBCNH, and SiBNH as a basic structure.

By using an alkyl-terminated or hydrogen-terminated flowable oligomer and keeping the substrate temperature at 100 degrees C. or less, sufficient fluidity can be ensured, and embeddability can be improved. From the viewpoint of obtaining better fluidity, the substrate temperature is more preferably 20 degrees C. to 30 degrees C. or less. However, even when the substrate temperature is as low as −50 degrees C., the fluidity of the flowable oligomer can be ensured.

### (Step S5: Vaporization Process)

In the vaporization process, the pressure inside the chamber is controlled to be equal to or lower than the vapor pressure of the flowable oligomer, so that the film of the flowable oligomer is partially vaporized and removed. For example, while stopping the processing gas, the pressure in the chamber is controlled to a pressure (referred to as a “second pressure”) lower than the pressure controlled in the flowable oligomer (flowable film) forming process (referred to as a “first pressure”). For example, the second pressure is controlled such that the pressure inside the chamber is equal to or lower than the vapor pressure of the flowable oligomer. By such pressure control, the flowable oligomer 202 film is partially vaporized, as illustrated in FIG. 2C. For example, the films of the flowable oligomer 202 on the top and sidewall portions of the recesses 201 are vaporized. At this time, the flowable oligomer 202 flows into the bottoms of the recesses 201 due to capillary action and remains there. As a result, the flowable oligomer 202 can be removed from the top and sidewall portions of the recesses 201, and a film can be formed (embedded) in a desired shape.

### (Step S7: Insulating Film Forming Process)

In the insulating film forming process, for example, the substrate may be annealed to cure the flowable oligomer in the recesses to form a dense and stable insulating film. The temperature at this time is preferably a high temperature exceeding 100 degrees C., more preferably equal to or higher than 150 degrees C. in order to solidify the film efficiently and reliably.

The annealing is preferably performed in a non-oxidizing atmosphere from the viewpoint of eliminating the influence of oxidation on a base, and may be performed in an inert gas atmosphere of N2 gas, a diluent gas (e.g., Ar gas or He gas), or the like. The annealing may include plasma processing to efficiently perform condensation and solidification. The annealing may be performed entirely by plasma processing or by a combination of thermal annealing and plasma annealing. Although only an inert gas may be used in the plasma processing, it is preferable to generate plasma containing a hydrogen-containing gas such as H2 gas to form the insulating film.

In addition, the plasma processing during the annealing is preferably performed by using a frequency in the range from the VHF band (30 to 300 MHz) to the microwave (MW) band (300 MHz to 3 THz). More preferably, the frequency is 60 MHz or higher. In the case of general ICP and CCP performed at a frequency of less than 30 MHz, film damage is likely to occur due to damage caused by high-energy ions exceeding 30 eV, but the film damage can be suppressed by using the frequency in the range from the VHF band to the MW band, particularly a frequency of 60 MHz or higher. That is, with the frequency in the range from the VHF band to the MW band, particularly the frequency of 60 MHz or higher, it is possible to emit ions and radicals with low energy of 30 eV or less, and the energy emitted to the film is low, making it possible to suppress film damage. In addition, element oxidation may also be suppressed. Among the frequencies of 60 MHz or higher, a frequency of 60 MHz or higher and 300 MHz or lower, which is within the VHF band, is more preferable.

In the insulating film forming process in step S7, the energy supplied to the substrate may be at least one of thermal energy, plasma energy, or UV energy. As a result, as illustrated in FIG. 2D, the flowable oligomer can be removed from the top and sidewall portions of the recesses 201, and the flowable oligomer 202 having a desired shape can be cured to form an insulating film 203.

The insulating film formed by the annealing in step S7 becomes a silicon-containing film or a boron-containing film when a silicon-containing gas or a boron-containing gas is used as the raw material gas. When the flowable oligomer contains any of the above-mentioned SiOH, SiNH, SiCOH, SiCNH, SiCH, BNH, BCNH, SiBCNH, and SiBNH as a basic structure, the insulating film will contain any of SiO₂, SiN, SiCO, SiCN, SiC, BN, BCN, SiBCN, and SiBN formed by condensation and solidification of the above-mentioned materials.

When the insulating film to be formed is a film containing carbon, such as the above-mentioned SiCO, SiCN, SiC, or SiBCN, preventing a decrease in the carbon concentration in the film can be considered in the annealing in step S7 by replenishing the carbon desorbed by the plasma annealing. For this purpose, as a gas supplied during the plasma annealing, a carbon-containing gas may be used to generate plasma, so that an insulating film containing carbon is formed. As the carbon-containing gas, a gas containing carbon and hydrogen such as CmHn (m is an integer of 1 or more, n is an integer of 2 or more) may be used. Plasma containing a gas containing carbon and hydrogen is more suitable for forming an insulating film containing carbon because the plasma contains carbon that has such an effect and the above-mentioned hydrogen.

### (Step S9: Insulating Film Thickness Determination Process)

Next, in step S9, it is determined whether the formed insulating film has a desired thickness. When it is determined that the insulating film does not have the desired thickness, the process returns to step S3 and the steps S3 to S7 are repeated. When it is determined that the insulating film has the desired thickness, the process is terminated. The number of times step S9 is repeated may be one or more times, or may be predetermined.

FIG. 3 illustrates an example of embedding an insulating film by using flowable CVD in a more complex structure with internal slits. In the structure 210 illustrated in (A) in FIG. 3, a plurality of horizontal openings 211 penetrating the structure in the depth direction are arranged in a vertical direction. The upper portions of (a) to (e) in FIG. 3 illustrate a cross sections when the structure 210 is cut in the vertical direction (the Y direction), and the lower portions illustrate cross sections when the structure 210 is cut in the horizontal direction (the X direction).

(a) in FIG. 3 illustrates the states of film formation of a flowable oligomer 212 on the horizontal openings 211, and the top and sidewall portions of the horizontal openings 211 when the flowable film forming process in step S3 is performed. (b) in FIG. 3 illustrates the vaporization and fluidization states of the flowable oligomer 212 when the vaporization process in step S5 is performed. In the vaporization process in step S5, the pressure inside the chamber is reduced and/or the substrate temperature is increased to vaporize and partially remove the flowable oligomer 212. As a result, the thin flowable oligomer 212 in the top and sidewall portions is partially removed. The thick flowable oligomer 212 in the horizontal openings 211 is vaporized and removed in the vicinity of the openings, but the flowable oligomer 212 in a liquid state enters the interiors of the horizontal openings 211 due to capillary action. As a result, the flowable film in the areas other than the horizontal openings 211 in the structure 210 can be removed, and the flowable oligomer 212 can be selectively embedded in the horizontal openings 211, so that a flowable oligomer 212 with a desired structure is obtained.

(c) in FIG. 3 illustrates the embedded state of the insulating film in the horizontal openings 211 when the processes up to the insulating film forming process in step S7 have been performed for one cycle (once). The flowable oligomer 212 in the horizontal openings 211 may be sufficiently modified and cured to form the insulating film 213.

(d) in FIG. 3 illustrates a state in which the second cycle (second time) of steps S3 to S5 is completed in a case where it is determined that the desired film thickness has not been reached after the process of determining the thickness of the insulating film in step S9 was performed, and (e) in FIG. 3 illustrates a state when the second cycle (second time) of step S7 is completed.

By performing steps S3, S5, and S7 in this order for a plurality of cycles, the insulating film 213 can be selectively embedded in the horizontal openings 211. In addition, by controlling the film thickness of the flowable oligomer 212 in steps S3 and S5, film quality can be sufficiently improved in step S7.

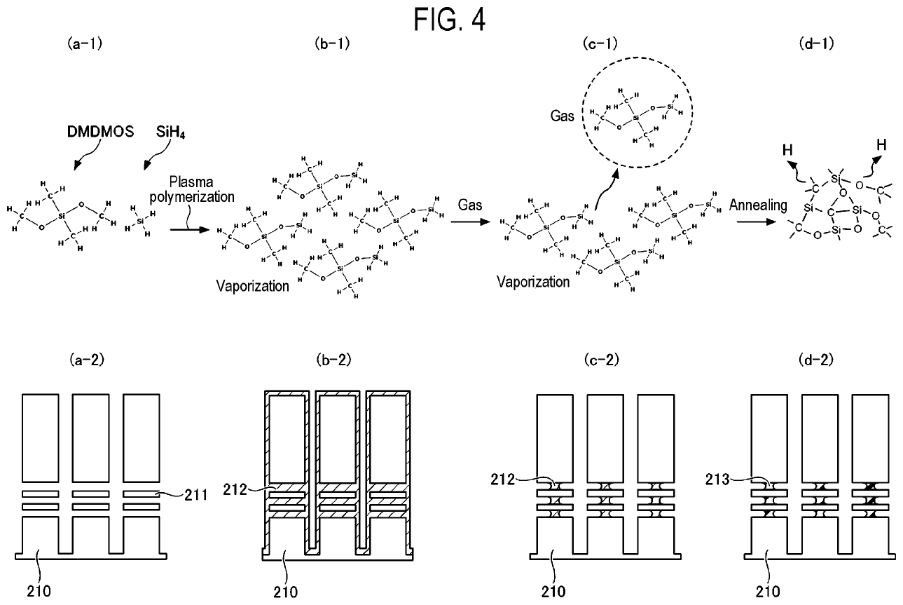

Next, a typical specific example of the present embodiment will be described with reference to FIG. 4. Here, first, dimethyldimethoxysilane (DMDMOS) is used as the raw material gas and silane gas (SiH₄ gas) is used as a non-oxidizing hydrogen-containing gas as illustrated in (a-1) in FIG. 4. The silane gas is plasmatized, and plasma polymerization in step S3 is performed at a temperature of 100 degrees C. or lower. As a result, a flowable oligomer 212 is generated and formed into a film. As a result, the flowable oligomer 212 illustrated in (b-1) in FIG. 4 is formed into a film on, for example, the structure 210 illustrated in (a-2) in FIG. 4, as illustrated in (b-2) in FIG. 4.

Next, the vaporization in step S5 is performed. In the vaporization in step S5, the pressure inside the chamber is reduced to be equal to or lower than the vapor pressure of the flowable oligomer 212, and some of the flowable oligomer 212 in a liquid state is vaporized as illustrated in (c-1) in FIG. 4. As a result, as illustrated in (c-2) in FIG. 4, the flowable oligomer 212 in the top, sidewall, bottom portions, and portions in the vicinity of the horizontal openings 211 of the structure 210 is partially vaporized and removed, and the flowable oligomer 212 inside the horizontal openings 211 remains.

Next, an annealing in step S7 is performed. The annealing in step S7 is a process including plasma processing performed with inert gas plasma or hydrogen-containing gas plasma at a temperature exceeding 100 degrees C., preferably at a temperature equal to or higher than 150 degrees C. by using energy of a frequency in the range from the VHF band to MW band, or the like. As a result, a network-structured SiOC film, which is a stable insulating film illustrated in (d-1) in FIG. 4 is formed. As a result, the flowable oligomer 212 is modified to form a network, and the insulating film 213 of the solid SiOC film illustrated in (d-2) in FIG. 4 is formed.

### Experimental Results

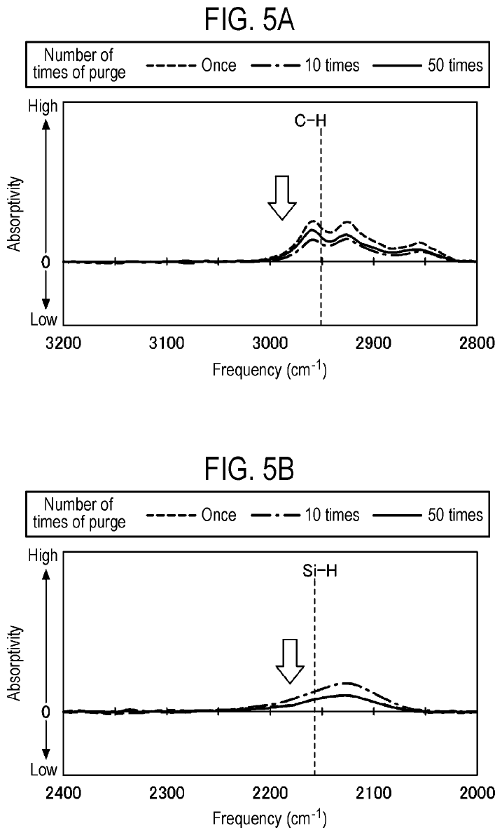

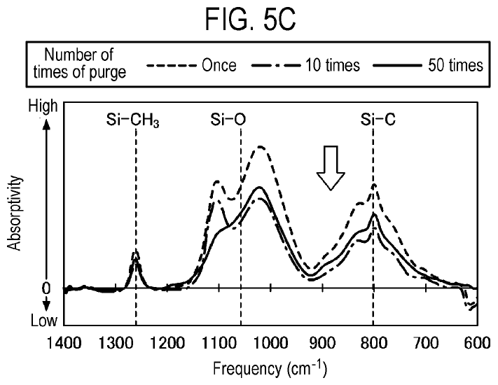

An example of the results of an FTIR analysis of a SiOC insulating film 213 formed by the insulating film forming method according to the first embodiment will be described with reference to FIGS. 5A to 5C. Process conditions for each process of the insulating film forming method according to the first embodiment are shown below.

### (Process Conditions for Forming Flowable Film (Step S3))

Substrate temperature: 25 degrees C.
Pressure: 3 Torr (400 Pa)
Gas type: DMDMOS, SiH₄, Ar, H₂
RF 50 W (frequency 13.56 MHz)

### (Process Conditions for Vaporization (Step S5))

Substrate temperature: 25 degrees C.
Pressure: 1 mTorr to 0.4 Torr (0.133 Pa to 53.3 Pa)
Gas type: Ar
Number of times of purge: once, 10 times, or 50 times

### (Process Conditions for Forming SiOC Film (Step S7))

Substrate temperature: 500 degrees C.
Pressure: 4 Torr (533 Pa)
Gas type: Ar

In the vaporization process, the interior of the chamber is evacuated to a reduced pressure of 1 mTorr to 0.4 Torr. In addition, the supply and stop of a diluent gas (e.g., Ar) are alternately repeated one or more times, and the diluent gas is exhausted by an exhaust mechanism. As a result, cycle purge in which evacuation and purge with the diluent gas are alternately repeated is performed. The number of times the supply and stop of the diluent gas are repeated is the number of times of purge.

The horizontal axis of each graph in FIGS. 5A to 5C represents wave number (cm⁻¹), and the vertical axis represents absorptivity. In each graph in FIGS. 5A to 5C, some of the flowable oligomer was vaporized by the vaporization process and the absorptivities of all of C—H bonds, Si—H bonds, Si—O bonds, and Si—C bonds were decreased when the number of times of purge increased. In particular, when the number of times of cycle purge was increased, Si—O bonds and Si—C bonds illustrated in FIG. 5C show significantly decreased absorptivity. From the experimental results, it was found that when the number of times of performing cycle purge increases, the vaporization efficiency of the flowable film increases.

### Second Embodiment

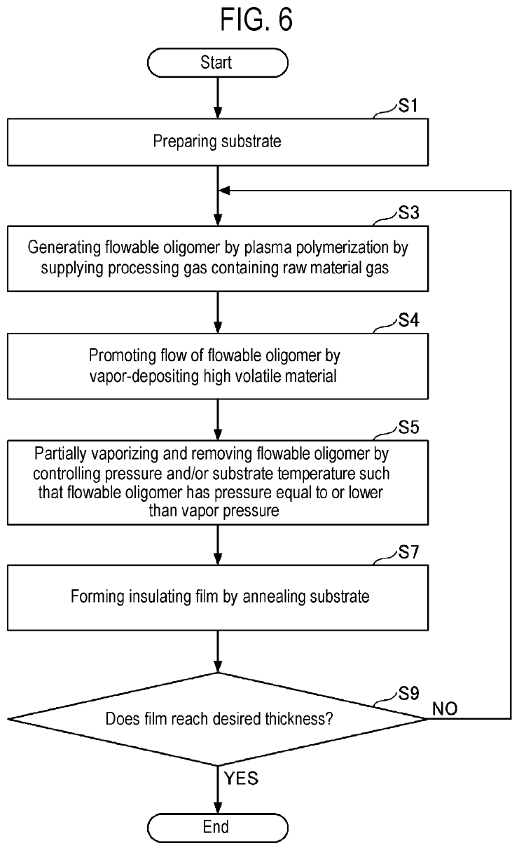

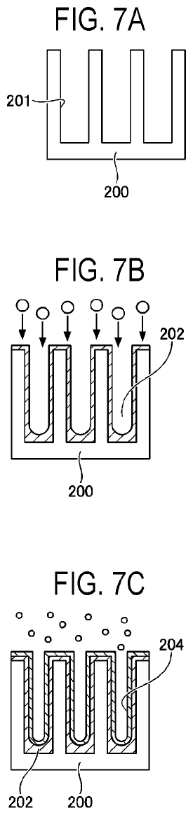

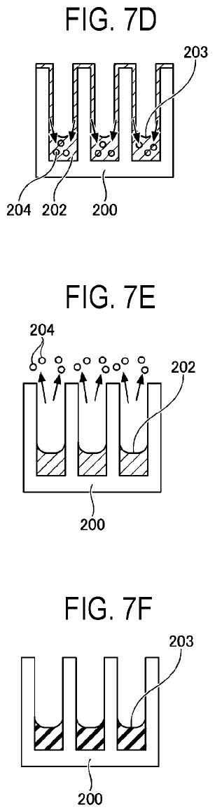

An insulating film forming method according to a second embodiment will be described with reference to FIGS. 6 and 7A to 7F. FIG. 6 is a flowchart illustrating an example of an insulating film forming method according to the second embodiment. FIGS. 7A to 7F are schematic views illustrating an insulating film forming process according to the second embodiment.

In the flowchart of FIG. 6, the same step numbers are assigned to the same processing steps as those of FIG. 1 illustrating the method of forming an insulating film according to the first embodiment. In the method of forming an insulating film according to the second embodiment, step S4 is added in addition to each step of the method of forming an insulating film according to the first embodiment. Therefore, in the second embodiment, step S4, which makes the second embodiment different from the first embodiment, will be mainly described.

The method of forming an insulating film according to the second embodiment includes preparing a substrate in a chamber in step S1, supplying a processing gas containing a raw material gas into the chamber in step S3, and generating a flowable oligomer by plasma polymerization and forming a flowable oligomer into a film on the substrate.

Next, in step S4, a highly volatile material is supplied and vapor-deposited on the substrate to promote the flow of the flowable oligomer film. Next, in step S5, the flowable oligomer is partially vaporized and removed. Next, in step S7, energy is supplied to the substrate to cure the flowable oligomer and form an insulating film in the recesses. In step S9, it is determined whether the insulating film has reached a predetermined thickness, and steps S3 to S7 are repeated until the insulating film reaches a predetermined thickness, and the process is terminated. The process in step S4 will be described in detail below.

### (Step S4: Vapor Deposition Step of Highly Volatile Material)

A vapor deposition process of a highly volatile material is performed between the film forming process of the flowable oligomer 202 in step S3 (see FIG. 7B) and the vaporization process in step S5 (see FIG. 7E). As a result, as illustrated in FIG. 7C, the highly volatile material 204 is vapor-deposited so as to be dissolved in the flowable oligomer. As a result, as illustrated in FIG. 7D, the flowable oligomer 202 can be diluted with the highly volatile material 204 to promote fluidity, and the flowable oligomer 202 can more easily flow into the recesses 201.

The highly volatile material 204 is preferably a material with a lower molecular weight than the flowable oligomer because it volatizes more easily. The vapor pressure of the highly volatile material 204 is equal to or lower than the vapor pressure of the raw material gas, but the highly volatile material 204 may be a high vapor pressure gas (such as CₓO_{y}H_{z}) with a vapor pressure equal to or higher than the vapor pressure of the film of the flowable oligomer. The high vapor pressure gas may be at least one of ethanol, IPA, acetone, or the raw material gas. As a result, the high vapor pressure gas can be volatized while being dissolved into the formed film of the flowable oligomer 202 to improve fluidity of the film. This allows the flowable oligomer 202 to be embedded in a more desired shape. The process conditions of steps S3, S5, and S7 are the same as described above, and the process conditions of step S4 are shown below.

### (Process Conditions for Vapor Deposition of High Volatile Material (Step S4))

Substrate temperature: Equal to or lower than annealing temperature in step S7 (≤100 degrees C.)
Pressure: Equal to or higher than vapor pressure of flowable oligomer (1 mTorr to 10 Torr (0.133 Pa to 1333 Pa))
High volatile material: High vapor pressure gas (CₓO_{y}H_{z} gas) with higher volatility than flowable oligomer

### Example 1

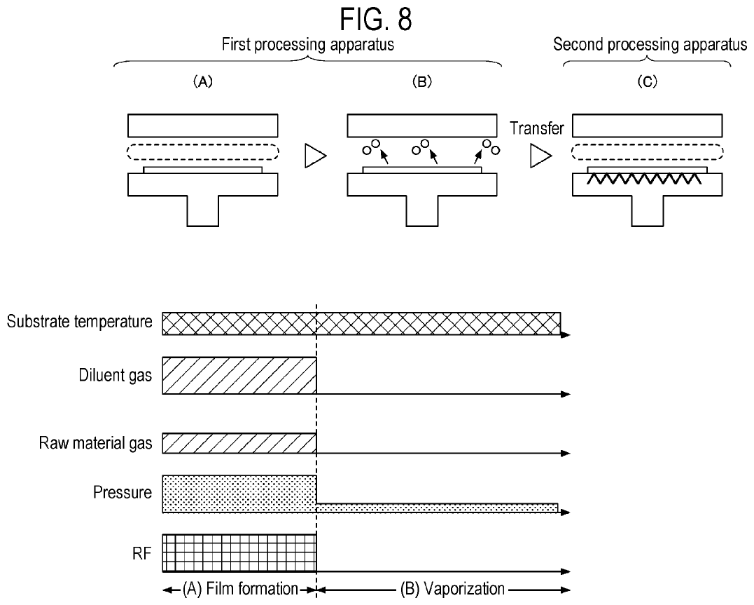

Regarding the methods of forming an insulating film according to the first embodiment and the second embodiment described above, Examples 1 to 7 will be described with reference to FIGS. 8 to 14. First, an insulating film forming method in Example 1 will be described with reference to FIG. 8. FIG. 8 is a view illustrating each process and a time chart of the method of forming an insulating film of Example 1.

Both the flowable oligomer film forming process in step S3 and the vaporization process in step S5 are preferably performed at a low temperature equal to or lower than 100 degrees C., and preferably performed in the same processing apparatus. In addition, the annealing process in step S7 is performed at a temperature exceeding 80 degrees C. to 100 degrees C., and more preferably at a high temperature equal to or higher than 150 degrees C. For this reason, it is preferable to perform step S7 in a separate processing apparatus from steps S3 and S5.

Therefore, in Example 1, as illustrated in the upper portion of FIG. 8, a flowable oligomer film forming process (A: corresponding to step S3) and a vaporization process (B: corresponding to step S5) are performed in the same processing apparatus (referred to as a “first processing apparatus”). On the other hand, an annealing process (C: corresponding to step S7) is performed by transferring the substrate to a processing apparatus (referred to as “second processing apparatus”) different from the first processing apparatus.

The time chart illustrated in the lower portion of FIG. 8 will be described. After the flowable oligomer film forming process (A) is performed in the first processing apparatus, the vaporization process (B) is performed. The feature of Example 1 is that, in the vaporization process (B), a vacuum is drawn by an exhaust mechanism while stopping the processing gas, the pressure inside the first processing apparatus is controlled to the second pressure lower than the first pressure, and the film of the flowable oligomer is vaporized. In the time chart, the annealing process (C) performed after the vaporization process (B) is omitted.

In Example 1, the process conditions for the flowable oligomer film forming process (A) are as follows: the substrate temperature is set to 0 degrees C., and processing gases (DMDMOS and SiH₄ as a raw material gas, and Ar and N₂ gases as a diluent gas) are supplied. In addition, RF power of 50 W with a frequency of, for example, 13.56 MHz is applied to plasmatize silane (SiH₄) gas or the like. As a result, a flowable oligomer is formed into a film by plasma-enhanced chemical vapor deposition (PECVD). The pressure within the first processing apparatus (first pressure) is controlled to, for example, 4 Torr (533 Pa).

In Example 1, the process conditions for the vaporization process (B) are as follows: while stopping the processing gases (a raw material gas and a diluent gas), vacuum is drawn by an exhaust mechanism, and the pressure inside the first processing apparatus is controlled to the second pressure lower than the first pressure (e.g., equal to or lower than the vapor pressure of the flowable oligomer). By controlling the vaporization time, the amount of vaporization of the flowable oligomer can be controlled, and the flowable oligomer in the top portions, the sidewall portions, or the like of the recesses can be partially vaporized. The substrate temperature is maintained at 0 degrees C. and RF power is turned off.

After performing the vaporization process (B), the substrate is transferred to the second processing apparatus, and then the annealing process (C) is performed. The process conditions at this time include controlling the substrate temperature to a temperature exceeding 100 degrees C. by using energy of heat, plasma, UV, or the like and the flowable oligomer is cured and modified in an inert gas atmosphere of N₂ gas, a diluent gas (e.g., Ar) or the like. The plasma processing during the annealing is preferably performed by using a frequency in the range from the VHF band (30 MHz to 300 MHz) to the microwave (MW) band (300 MHz to 3 THz). This makes it possible to form an insulating film in the recesses of the substrate.

### Example 2

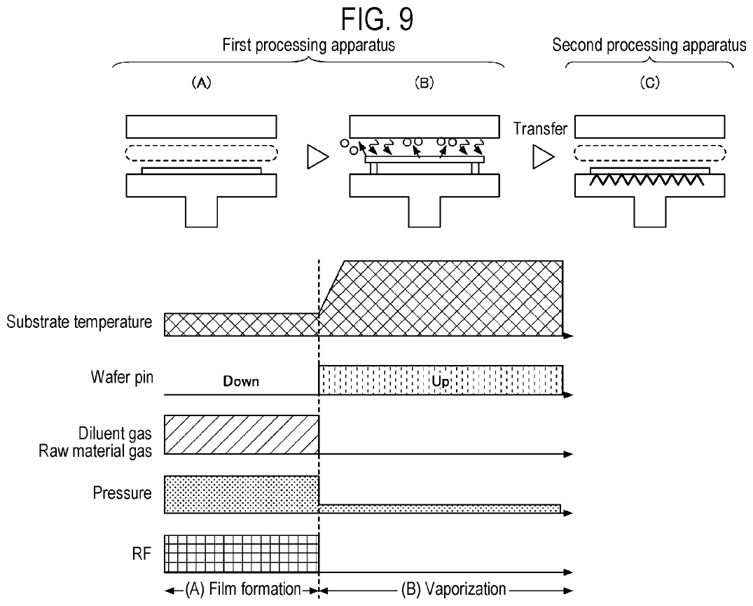

Next, an insulating film forming method in Example 2 will be described with reference to FIG. 9. In Example 2, as illustrated in the upper portion of FIG. 9, a film forming process (A) and a vaporization process (B) are performed in the first processing apparatus, and an annealing process (C) is performed in the second processing apparatus.

The time chart illustrated in the lower portion of FIG. 9 will be described. After the flowable oligomer film forming process (A) is performed in the first processing apparatus, the vaporization process (B) is performed. The feature of Example 2 is that after the film forming process (A) is performed with a substrate placed on a stage, the vaporization process (B) is performed with the substrate separated from the stage. As a result, in the vaporization process (B), while stopping the processing gas, the substrate temperature may be controlled to the second substrate temperature higher than the first substrate temperature controlled in the film forming process (A) to partially vaporize the film of the flowable oligomer. In the time chart, the annealing process (C) performed after the vaporization process (B) is omitted.

The process conditions for the film forming process (A) may be the same as in Example 1, and, for example, the substrate temperature is controlled to 0 degrees C. Although illustration of control for RF power is omitted in the time chart, the same control as in FIG. 8 may be performed.

As for the process conditions for the vaporization process (B) in Example 2, pins for raising and lowering the substrate from the stage are raised. As a result, the substrate is separated from the stage and brought closer to a shower head having a high temperature of about 200 degrees C. and installed on the ceiling of the first processing apparatus (see (B) in FIG. 9) to raise the substrate temperature from about 0 degrees C. to 50 degrees C. As a result, the flowable oligomer in the top portions, sidewall portions, or the like of the recesses of the substrate can be partially vaporized.

In addition, in Example 2, as in Example 1, while stopping the processing gas, a vacuum may be drawn by an exhaust mechanism, and the pressure inside the first processing apparatus may be controlled to the second pressure lower than the first pressure, for example, equal to or lower than the vapor pressure of the flowable oligomer. In addition, cycle purge in Example 3, which will be described later, may be performed. As a result, partial vaporization of the flowable oligomer in the top portions, sidewall portions, or the like of the recesses of the substrate can be promoted.

After the substrate is transferred to the second processing apparatus, the annealing process (C) is performed. The process conditions at this time may be the same as in Example 1.

### Example 3

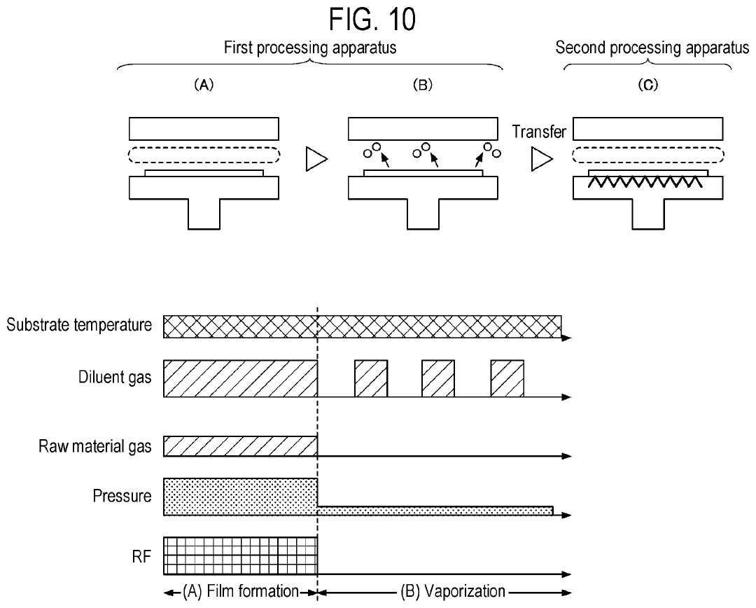

Next, an insulating film forming method in Example 3 will be described with reference to FIG. 10. In Example 3, as illustrated in the upper portion of FIG. 10, a film forming process (A) and a vaporization process (B) are performed in the first processing apparatus, and an annealing process (C) is performed in the second processing apparatus.

The time chart illustrated in the lower portion of FIG. 10 will be described. After the flowable oligomer film forming process (A) is performed in the first processing apparatus, the vaporization process (B) is performed. The feature of Example 3 is that, in the vaporization process (B), cycle purge in which supply and stop of the diluent gas are controlled so as to be alternately repeated is performed, thereby vaporizing the flowable oligomer film.

The process conditions for the film forming process (A) may be the same as in Example 1.

As for the process conditions for the vaporization process (B) in Example 3, supply and stop of the diluent gas are alternately repeated while stopping the raw material gas, and the diluent gas is exhausted by an exhaust mechanism. As a result, a cycle purge in which evacuation and purge with the diluent gas are alternately repeated is performed. The vaporization of the flowable oligomer can be promoted by the cycle purge.

After the substrate is transferred to the second processing apparatus, the annealing process (C) is performed. The process conditions at this time may be the same as in Example 1.

### Example 4

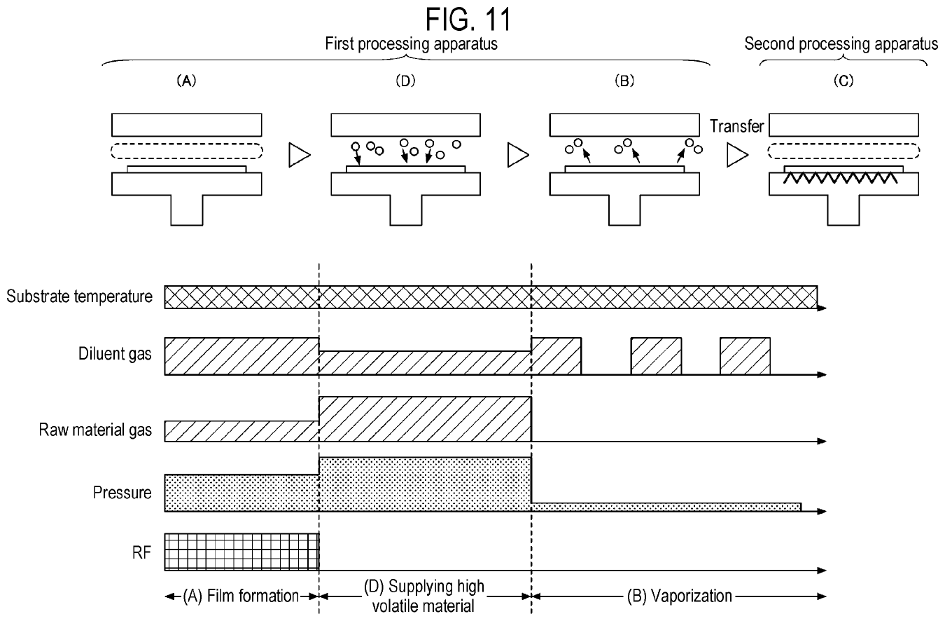

Next, an insulating film forming method in Example 4 will be described with reference to FIG. 11. In Example 4, as illustrated in the upper portion of FIG. 11, a film forming process (A), a vaporization process (B), and a vapor deposition process (D) are performed in the first processing apparatus, and an annealing process (C) is performed in the second processing apparatus. The feature of Example 4 is that the vapor deposition process (D) is further included in which high vapor pressure gas is supplied after the film forming process (A) and before the vaporization process (B) to promote the flow of the flowable oligomer film.

The time chart illustrated in the lower portion of FIG. 11 will be described. After performing the flowable oligomer film forming process (A) in the first processing apparatus, a highly volatile material is supplied and the vapor deposition process (D) is performed. This promotes the flow of the flowable oligomer film. Thereafter, the vaporization process (B) is performed.

The process conditions for the film forming process (A) may be the same as in Example 1. As for the process conditions of the vaporization process (B), the example in FIG. 11 illustrates the same process conditions as in Example 3 in which cycle purge is performed, but the process conditions may be the same as those in Example 1 or Example 2 without being limited thereto.

As the process conditions for the vapor deposition process (D), the flow rate of the diluent gas is reduced to be lower than the flow rate of the diluent gas in the film forming process (A), and the flow rate of the raw material gas (DMDMOS and silane gas) is increased. As a result, the molar fraction m of the raw material gas is increased, and the partial pressure p of the raw material gas with respect to the pressure (total pressure P) of the total gas (mixed gas), which is expressed as P×m, is increased. In addition, as long as the partial pressure p of the raw material gas relative to the total pressure P can be increased, the flow rate of the diluent gas does not need to be reduced.

In the raw material gas, it is preferable to increase the DMDMOS and stop the silane gas. This is because the silane gas has a small molecular weight, and even when the partial pressure of the raw material gas is increased by increasing the amount of the silane gas, it is difficult to liquefy the flowable oligomer. On the other hand, the DMDMOS has a large molecular weight and can easily liquefy the flowable oligomer. The increased DMDMOS is an example of a high vapor pressure gas (highly volatile material) which has its vapor pressure lower than the vapor pressure of the raw material gas and higher than the vapor pressure of the flowable oligomer film.

In addition, as illustrated in FIG. 11, the pressure in the vapor deposition process (D) (referred to as a “third pressure”) may be controlled to be higher than the pressure in the film forming process (A) (the first pressure).

Furthermore, a high vapor pressure gas other than the DMDMOS may be supplied in the vapor deposition process (D). By increasing the partial pressure of the high vapor pressure gas relative to the total pressure of all of the gases, the high vapor pressure gas is easily vapor-deposited onto the flowable oligomer, so that the high vapor pressure gas is dissolved into the flowable oligomer, and the flow of the flowable oligomer is promoted.

The high vapor pressure gas supplied in the vapor deposition process (D) is a highly volatile material which has its vapor pressure lower than the vapor pressure of the raw material gas. That is, the raw material gas itself may also function as the high vapor pressure gas. The high vapor pressure gas not only liquefies the flowable oligomer, but also liquefies the raw material gas itself. By using the raw material gas as the high vapor pressure gas, switching of gases may be made unnecessary. The high vapor pressure gas other than the raw material gas may be at least one of ethanol, IPA, or acetone.

In the vapor deposition process (D), the flowable oligomer may be liquefied by either increasing the partial pressure of the raw material gas or supplying the high vapor pressure gas, and creating, inside the processing apparatus, an environment with a pressure equal to or lower than the vapor pressure of the raw material gas. Alternatively, the pressure within the processing apparatus may be increased.

Thereafter, in the vaporization process (B), the supply of the raw material gas is stopped and the flow rate of the diluent gas is increased to perform cycle purge, causing vaporization and flow of the raw material gas in which the high vapor pressure gas has been dissolved.

After the substrate is transferred to the second processing apparatus, the annealing process (C) is performed. The process conditions at this time may be the same as in Example 1.

In the vaporization process (B), supply and stop of the diluent gas are controlled so as to be alternately repeated, thereby vaporizing the flowable oligomer film. However, the vaporization process (B) is not limited to this, and may be performed by using at least one of the methods of Examples 1 to 3.

In Example 4, the fluidity is improved by diluting the flowable oligomer with a highly volatile material, so that the flowable oligomer can more easily flow into the recesses.

### Example 5

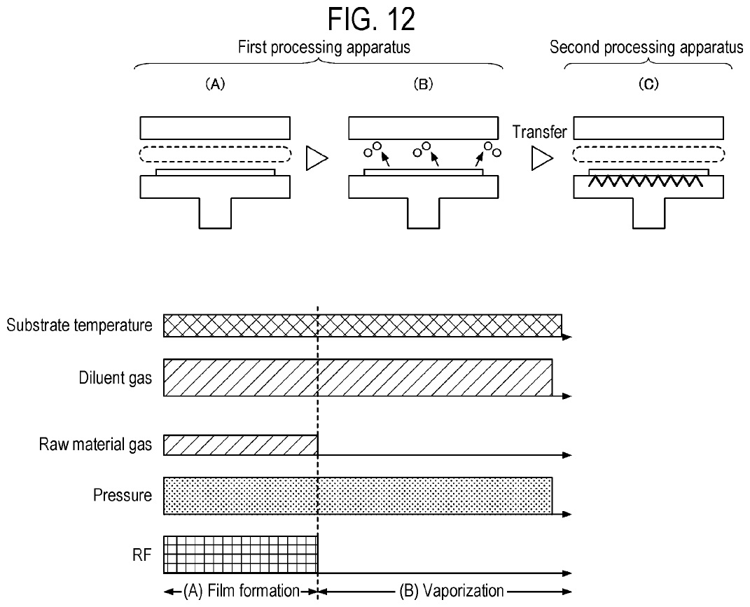

Next, an insulating film forming method in Example 5 will be described with reference to FIG. 12. In Example 5, as illustrated in the upper portion of FIG. 12, a film forming process (A) and a vaporization process (B) are performed in the first processing apparatus, and an annealing process (C) is performed in the second processing apparatus.

The time chart illustrated in the lower portion of FIG. 12 will be described. In Example 5, after the flowable oligomer film forming process (A) is performed in the first processing apparatus, the vaporization process (B) is performed. The process conditions for the film forming process (A) may be the same as in Example 1. The feature of Example 5 is that, in the vaporization process (B), the raw material gas is stopped while maintaining the flow rate and pressure of the diluent gas supplied in the film forming process (A), and the flowable oligomer formed into a film is vaporized by purging.

In Example 5, the flowable oligomer is vaporized in the vaporization process (B) by purging with the diluent gas by maintaining the flow rate of the diluent gas instead of the cycle purge in Example 3. The pressure controlled in the vaporization process (B) may be the same as the pressure controlled in the film forming process (A), or may be lower than that pressure.

### Example 6

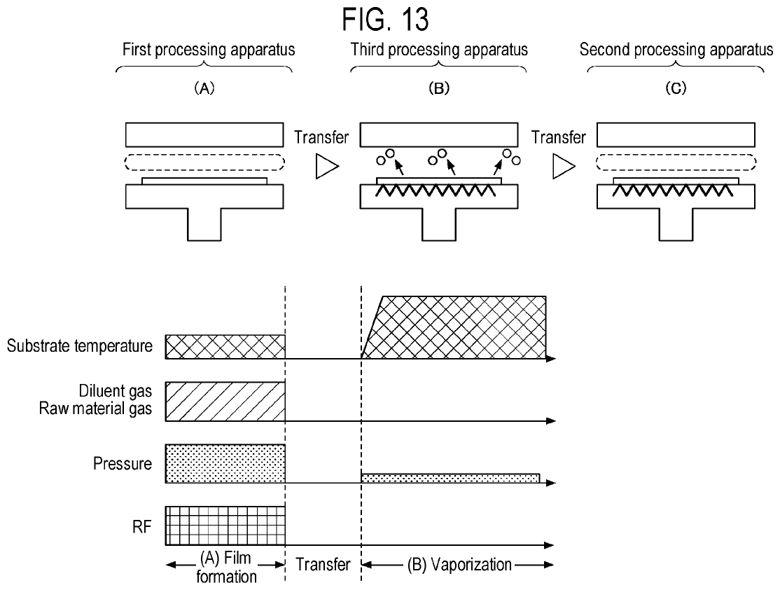

Next, an insulating film forming method in Example 6 will be described with reference to FIG. 13. In Example 6, as illustrated in the upper portion of FIG. 13, a film forming process (A), a vaporization process (B), and an annealing process (C) are performed in separate processing apparatuses, respectively. Here, the film forming process (A) is performed in the first processing apparatus, the vaporization process (B) is performed in the third processing apparatus, and the annealing process (C) is performed in the second processing apparatus.

By performing the vaporization process (B) in a separate processing apparatus from the film forming process (A), there is no temperature restriction on the process conditions in the vaporization process (B), and controllability is improved. For example, in the vaporization process (B), the substrate temperature can be controlled so as to be higher than the substrate temperature in the film forming process (A) and to be lower than the substrate temperature in the annealing process (C).

For example, the substrate temperature in the film forming process (A) is controlled to 0 degrees C., and the substrate temperature in the annealing process (C) is controlled to 100 degrees C. In this case, as illustrated in the lower portion of FIG. 13, the substrate temperature in the vaporization process (B) can be controlled to an intermediate temperature, such as 50 degrees C., between the substrate temperatures in the film forming process (A) and the annealing process (C). As a result, the controllability of the vaporization process (B) can be improved and partial vaporization of the flowable oligomer can be promoted. In the vaporization process (B) in FIG. 13, the diluent gas and pressure are omitted, but as described above, the diluent gas and pressure can be controlled in the same manner as the vaporization process (B) in Examples 1 to 3 and Example 5.

### Example 7

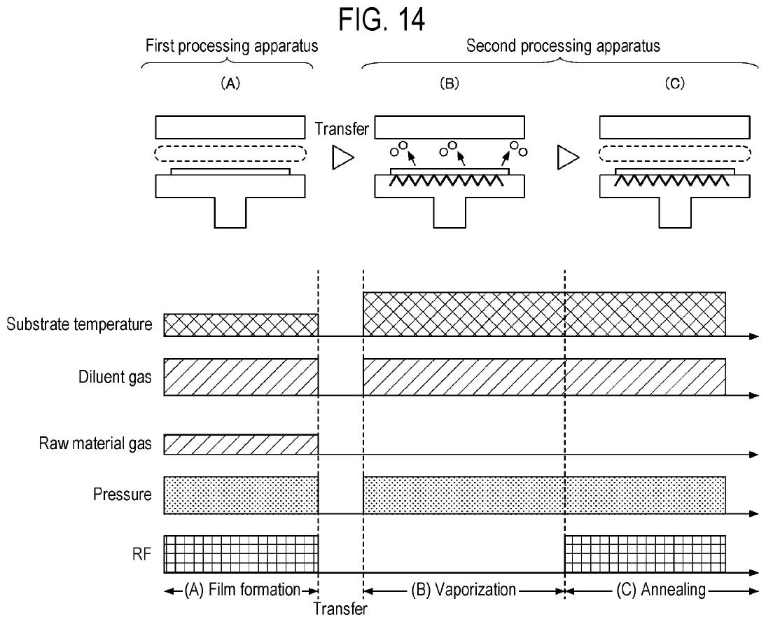

Next, an insulating film forming method in Example 7 will be described with reference to FIG. 14. In Example 7, as illustrated in the upper portion of FIG. 14, a film forming process (A) is performed in the first processing apparatus, and a vaporization process (B) and an annealing process (C) are performed in the second processing apparatuses.

The time chart illustrated in the lower portion of FIG. 14 will be described. After performing the flowable oligomer film forming process (A) in the first processing apparatus, the substrate is transferred to the second processing apparatus, and the vaporization process (B) is performed. In the vaporization process (B), the substrate temperature is increased to vaporize the film of the flowable oligomer.

The process conditions for the film forming process (A) may be the same as in Example 1, and, for example, the substrate temperature is controlled to 0 degrees C.

After the film forming process (A) is performed in the first processing apparatus, the substrate is transferred to the second processing apparatus, and the vaporization process (B) is performed. As a process condition for the vaporization process (B), for example, the substrate temperature is controlled to be higher than 0 degrees C. and lower than 100 degrees C. By stopping the supply of the raw material gas and heating the substrate while maintaining the flow rate and pressure of the diluent gas, vaporization of the flowable oligomer can be promoted and the flowable oligomer can be partially vaporized. In addition, it is illustrated that the flow rate and pressure of the diluent gas in the film forming process (A) are maintained in the vaporization process (B) in FIG. 14, but as described above, the flow rate and pressure of the diluent gas can be controlled in the same manner as the vaporization process (B) in Examples 1 to 3 and Example 5.

Next, the annealing process (C) is performed. As the process conditions at this time, the substrate temperature is controlled to be the same as or higher than that in the vaporization process (B). In addition, RF power is applied to generate plasma, and annealing is performed by using the plasma. By using the plasma, the flowable oligomer can be modified and cured.

For example, in the case where the flowable oligomer is of a type that has a high vapor pressure and is easily vaporized, there is a possibility that the flowable oligomer can be vaporized by decompression (evacuation) or purge with the diluent gas at a relatively low temperature. On the other hand, in the case where the flowable oligomer is of a type that has a low vapor pressure and is difficult to vaporize, it is necessary to raise the substrate temperature or lower the pressure while raising the substrate temperature. In such a case, in order to keep the substrate temperature higher in the vaporization process (B), it is better to perform the vaporization process (B) in a processing apparatus that is different from the processing apparatus in which the film formation process (A) is performed.

In Example 7, when the flowable oligomer does not vaporize unless it is at a relatively high temperature, the substrate temperature in the vaporization process (B) may be controlled to a higher temperature than the substrate temperature controlled in the film forming process (A) by performing the film forming process (A) and the vaporization process (B) in different processing apparatuses. This makes it possible to sufficiently vaporize a flowable oligomer even when the flowable oligomer is of a type that has a relatively low vapor pressure and is difficult to vaporize.

In Example 7, vaporization and flow are simultaneously caused by heating the substrate under a reduced pressure in the vaporization process (B), and then RF power is applied to generate plasma, and the annealing process (C) is performed by using the plasma. In the annealing process (C), the substrate temperature is controlled to be higher than the substrate temperature controlled in the vaporization process (B).

According to Example 7, the control range of the substrate temperature in the vaporization process (B) can be increased by performing the film forming process (A), the vaporization process (B), and the annealing process (C) in separate processing apparatuses, respectively. As a result, even if the flowable oligomer is a flowable oligomer which is not vaporized unless a relatively high temperature is made, the flowable oligomer can be partially vaporized by making the substrate temperature controlled in the vaporization process (B) higher than the substrate temperature controlled in the film forming process (A).

### Experimental Results 2

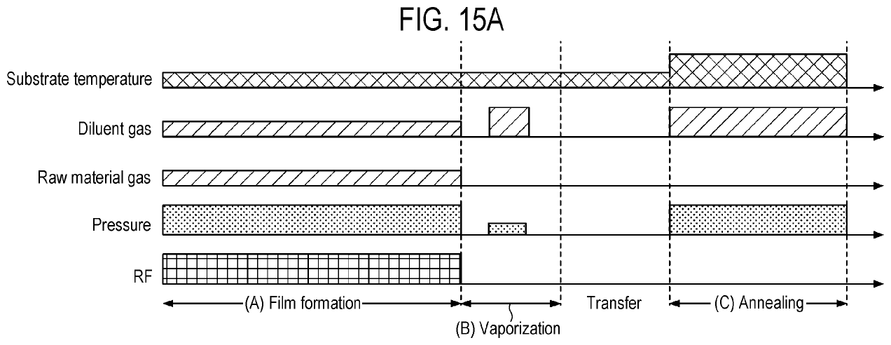

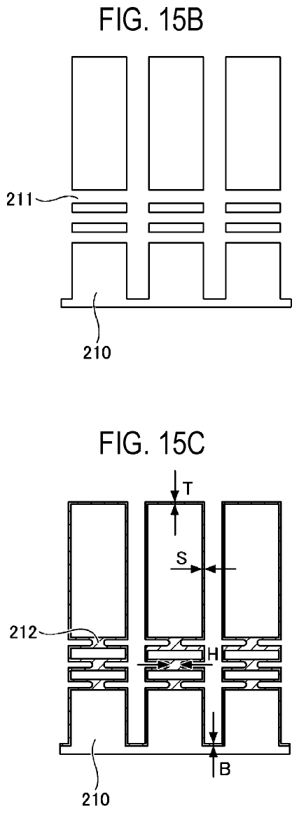

Experimental results 2 obtained by measuring the thicknesses of the insulating films (SiOC films) formed in Example 3 in which cycle purge is performed will be described with reference to FIGS. 15A to 15C. The process conditions for each process illustrated in FIG. 15A for forming insulating films used in this experiment are shown below.

### (Process Conditions for Film Forming Process (A)>

Substrate temperature: −10 degrees C.
Pressure: 3 Torr (400 Pa)
Gas type: DMDMOS, SiH₄, Ar, H₂
RF 50 W (13.56 MHz)

### (Process Conditions for Vaporization Process (B)>

Substrate temperature: −10 degrees C.
Pressure: 1 mTorr to 0.4 Torr (0.133 Pa to 53.3 Pa)
Gas type: Ar
Number of times of purge: once

### (Process Conditions for Annealing Process (C))

Substrate temperature: 500 degrees C.
Pressure: 4 Torr (533 Pa)
Gas type: Ar

The vaporization process (B) was performed on the film of the flowable oligomer 212 on the structure 210 illustrated in FIG. 15B, and the flowable oligomer 212 was partially vaporized. The flowable oligomer 212 was cured in the annealing process (C), and an insulating film was formed. The film thicknesses of the flowable oligomer 212 after the vaporization process (B) were measured.

As a result of the measurement, the film thickness T in the top portions and the film thickness S in the sidewall portions of the film of the flowable oligomer 212 formed on the structure 210 in FIG. 15C, were less than 1 nm. The film thickness H of the film of the flowable oligomer 212 formed inside the horizontal openings 211 in the structure 210 was 13.5 nm. In the film of the flowable oligomer 212 formed on the structure 210, the film thickness B in the bottom portions was less than 1 nm.

From the foregoing, it has been found that the flowable oligomer 212 formed on the top portions, sidewalls, and bottom portions of the recesses in the structure 210 can be partially vaporized and removed by the vaporization process (B). In addition, it has been found that the film of the flowable oligomer 212 formed inside the horizontal openings 211 can be controlled to have a desired thickness. As a result, the flowable oligomer 212 can be selectively embedded in the horizontal openings 211. Furthermore, the film thickness of the flowable oligomer 212 that is cured and modified in the annealing process (C) can be controlled, and the film quality can be sufficiently improved.

### [Substrate Processing System]

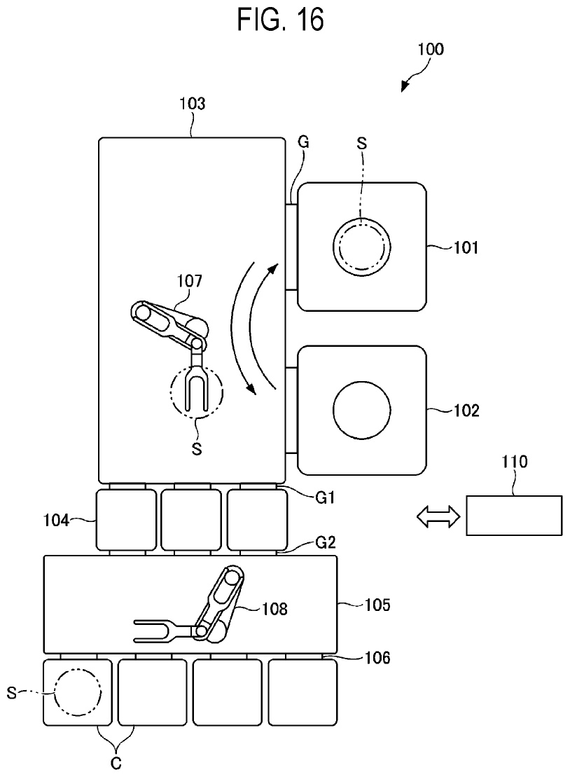

Next, an example of a substrate processing system that implements the above-described methods of forming an insulating film will be described. FIG. 16 is a schematic configuration view illustrating an example of a substrate processing system. As illustrated in FIG. 16, a substrate processing system 100 forms an insulating film on a substrate S, and includes a first processing apparatus 101 and a second processing apparatus 102. These apparatuses are connected to a wall of a vacuum transfer chamber 103 via gate valves G, respectively. The interior of the vacuum transfer chamber 103 is exhausted by a vacuum pump to be maintained at a predetermined degree of vacuum. The substrate processing system 100 may include a third processing apparatus (not illustrated) in addition to the first processing apparatus 101 and the second processing apparatus 102. The third processing apparatus is connected to the wall of the vacuum transfer chamber 103 via a gate valve G.

The first processing apparatus 101 performs the generation and film formation of a flowable oligomer in step S3 and the vaporization in step S5 of FIGS. 1 and 6, and the vapor deposition of a highly volatile material in step S4 of FIG. 6. In addition, the second processing apparatus 102 performs the annealing in step S37 in FIGS. 1 and 6. However, in Example 6 of FIG. 13, the vaporization in step S5 is performed by a third processing apparatus (not illustrated). In addition, in Example 7 of FIG. 14, the vaporization in step S5 is performed by the second processing apparatus 102.

In addition, three load-lock chambers 104 are connected to another wall of the vacuum transfer chamber 103 via gate valves G1, respectively. An atmospheric transfer chamber 105 is provided on the side opposite to the vacuum transfer chamber 103, with the load-lock chambers 104 interposed therebetween. Three load-lock chambers 104 are connected to the atmospheric transfer chamber 105 via gate valves G2, respectively. The load-lock chambers 104 perform pressure control between atmospheric pressure and vacuum when substrates S are transferred between the atmospheric transfer chamber 105 and the vacuum transfer chamber 103.

In the wall of the atmospheric transfer chamber 105 opposite to the wall to which the load-lock chambers 104 are connected, four carrier-mounting ports 106 in each of which a carrier (a FOUP or the like) C accommodating substrates S is installed are provided.

In the vacuum transfer chamber 103, a first substrate transfer mechanism 107 is provided. The first transfer mechanism 107 transfers the substrates S to the first processing apparatus 101, the second processing apparatus 102, and the load-lock chambers 104.

A second transfer mechanism 108 is provided within the atmospheric transfer chamber 105. The second transfer mechanism 108 transfers the substrates S to the carriers C and the load-lock chambers 104.

The substrate processing system 100 has a controller 110. The controller 110 controls each component of the first processing apparatus 101 and the second processing apparatus 102, the exhaust mechanism of the vacuum transfer chamber 103, the exhaust mechanism of the load-lock chambers 104, the first transfer mechanism 107, the second transfer mechanism 108, the gate valves G, G1, and G2, and the like. The controller 110 includes a main controller including a CPU, an input device, an output device, a display device, and a storage device (storage medium). The main controller of the controller 110 controls the processing of the substrate processing system 100 based on, for example, processing recipes stored in a non-transitory computer-readable storage medium built into the storage device or a storage medium set in the storage device.

Next, the operation of the substrate processing system 100 configured as described above will be described. First, a substrate S is taken out from each of the carriers C by the second transfer mechanism 108 and carried into any of the load-lock chambers 104. After the load-lock chambers 104 are evacuated, the substrates S in the load-lock chambers 104 are transferred into the first processing apparatus 101 by the first transfer mechanism 107.

In the first processing apparatus 101, generation of a flowable oligomer by plasma polymerization and film formation on a substrate S in step S3 are performed. Subsequently, the vaporization in step S5 is performed. The vapor deposition of a highly volatile material in step S4 may be performed between step S3 and step S5. In these steps, the substrate temperature is controlled to be less than 100 degrees C., and the steps are repeated multiple times as necessary.

After the processing in the first processing apparatus 101 is completed, the substrate S is taken out by the first transfer mechanism 107 and transferred to the second processing apparatus 102. In the second processing apparatus 102, the annealing in step S7 is performed at a high temperature exceeding 100 degrees C., preferably 150 degrees C. or higher.

After the process in the second processing apparatus 102 is completed, as necessary, the substrate S is transferred to the first processing apparatus 101 by the first transfer mechanism 107 so that the processes in step S3, step S4, and step S5 are performed, and then the substrate S is transferred to the second processing apparatus 102 so that the process in step S7 is performed.

After performing steps S3 to S7 a desired number of times, the first transfer mechanism 107 transfers the substrate S to one of the load-lock chambers 104. After the load-lock chamber 104 is returned to the air atmosphere, the substrate S therein is returned to the carrier C by the second transfer mechanism 108.

The above-described processes are performed simultaneously on a plurality of substrates S, and the insulating film forming process on a predetermined number of substrates S is completed.

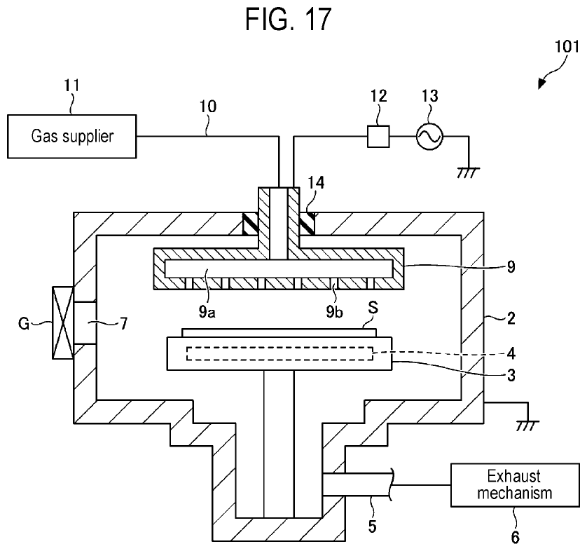

Next, a description will be made of a first processing apparatus that performs the generation and film formation of a flowable oligomer in step S3, the vaporization in step S5, and the vapor deposition of a highly volatile material in step S4 of FIG. 6. FIG. 17 is a cross-sectional view illustrating an example of the first processing apparatus. As illustrated in FIG. 17, the first processing apparatus 101 has a chamber 2. The chamber 2 is grounded. A stage 3 configured to horizontally place thereon a substrate S is provided in the chamber 2. The stage 3 is made of metal, and a temperature controller 4 configured to control the temperature of the substrate S is provided inside the stage 3. The stage 3 is grounded via the chamber 2.

An exhaust pipe 5 is connected to the bottom portion of the chamber 2, and an exhaust mechanism 6 having a function of controlling the pressure inside the chamber 2 is connected to the exhaust pipe 5. A transfer port 7 through which a substrate S is transferred is formed in the side wall of the chamber 2, and the transfer port 7 is opened/closed by a gate valve G.

A gas shower head 9 is provided in the upper portion of the chamber 2 to face the stage 3. The gas shower head 9 has a gas chamber 9a therein, and has a plurality of gas ejection holes 9b in the bottom portion thereof. The gas shower head 9 and the ceiling wall of the chamber 2 are insulated from each other by an insulating member 14.

A gas supply 11 is connected to the gas shower head 9 via a gas flow path 10. The gas supply 11 supplies a raw-material gas (including, for example, DMDMOS and a non-oxidizing hydrogen-containing gas (e.g., SiH₄ gas)), H₂ gas, an inert gas, and the like. The inert gas is supplied as a carrier gas, a diluent gas, a plasma generation gas, or the like. These gases reach the gas chamber 9a of the gas shower head 9 from the gas supply 11 via the gas flow path 10, and are ejected into the chamber 2 through the gas ejection holes 9b.

A radio-frequency power supply 13 is connected to the gas shower head 9 via a matcher 12. The radio-frequency power supply 13 applies radio-frequency power of, for example, 13.56 MHz, to the gas shower head 9. When the radio-frequency power is applied to the gas shower head 9, a radio-frequency electric field is formed between the gas shower head 9 and the stage 3, and capacitively coupled plasma is generated by the gas ejected from the gas shower head 9.

In the first processing apparatus 101, the substrate S is placed on the stage 3, and the temperature of the substrate S is controlled by a temperature controller 4 to be preferably lower than 100 degrees C., more preferably equal to or lower than 30 degrees C., and the pressure is controlled to 13 to 1,330 Pa. A raw material gas and a non-oxidizing hydrogen-containing gas are supplied from the gas supply 11 into the chamber 2 via the gas shower head 9, and radio-frequency power is supplied from the radio-frequency power supply 13 to the gas shower head 9. As a result, a flowable oligomer is generated by plasma polymerization and is formed into a film on the substrate S. Then, the flowable oligomer is then embedded in gaps (recesses) formed in the substrate S.

After forming the flowable oligomer film as described above, with the substrate S still placed on the stage 3, the temperature of the substrate S is maintained at the same low temperature as during the generation and film formation of the flowable oligomer. Then, H₂ gas and inert gas are supplied from the gas supply 11 into the chamber 2 via the gas shower head 9, and radio-frequency power is supplied from the radio-frequency power supply 13 to the gas shower head. As a result, the plasma processing is performed such that the flowable oligomer film is at least partially hydrogen-terminated while maintaining its fluidity.

As the second processing apparatus 102 that performs the annealing in step S7, one that includes, for example, a chamber, a stage, a heating mechanism configured to heat a substrate, a gas supply mechanism, an exhaust mechanism, and a plasma generation mechanism configured to generate plasma by a radio-frequency in the range from the VHF band to the MW band is exemplified. As the plasma generation mechanism, one configured to apply radio-frequency power in the VHF band to an electrode provided opposite to the stage, or one configured to radiate microwaves, which are oscillated from a microwave oscillation source, from an antenna provided to face the stage may be used.

In modifying by annealing, a greater modifying effect can be expected when the supplied gas has a higher temperature. In order to raise the temperature of the gas supplied to the second processing apparatus 102, the temperature of the gas supply to the second processing apparatus 102 is preferably high, and preferably exceeds 100 degrees C. However, since a dielectric ceiling plate is essential in the case of microwave plasma, there is a concern that the ceiling plate may be damaged, and it is difficult to raise the temperature sufficiently. On the other hand, in the case of VHF plasma, since it is possible to use a shower head made of metal as the gas supply, the temperature of the gas supply may be raised to exceed 80 degrees C. without any problem. For these reasons, it is desirable that the frequency during the annealing using plasma is preferably in the VHF band, which allows the use of a shower head made of metal, and in the VHF band, the above-mentioned range of 60 MHz or more, i.e., the range from 60 MHz to 300 MHz is preferable.

In the substrate processing system 100, both the film formation in step S3 and the vaporization in step S5 are performed in the same processing space of the first processing apparatus 101, but step S3 and step S5 may be performed in separate apparatuses or in separate processing spaces, respectively.

As described above, according to the insulating film forming method and the substrate processing system of the present embodiment, it is possible to embed an insulating film in desired shape by using a flowable film. In addition, film quality can be sufficiently improved by annealing.

### Other Applications

The insulating film forming methods and substrate processing systems according to the embodiments disclosed herein are exemplary in all respects and should not be considered restrictive. The embodiments may be modified and improved in various forms without departing from the scope and spirit of the appended claims. The matters described in the plurality of embodiments described above may take other configurations within the non-contradictory range and may be combined within the non-contradictory range.

For example, each of Examples 1, 3, and 5 is executed separately. Furthermore, each of Examples 6 and 7 is executed separately. Other examples may be combined. Furthermore, combinations of two or more other examples are possible.

For example, in the above-described embodiments, a case where a Si-containing gas or a B-containing gas is used as a raw material gas to form a Si-containing film or a B-containing film as an insulating film has been described, but the present disclosure is not limited thereto. For example, as a precursor and an insulating film, by using a gas containing any of the elements: tin (Sn), aluminum (Al), hafnium (Hf), and zirconium (Zr), a high-k film or a metal-containing film containing any of these elements may be formed.

In addition, the substrate processing system and the processing apparatuses that perform film formation and the like described in the above-described embodiments are merely examples. Furthermore, although a semiconductor substrate of silicon or the like (a semiconductor wafer) has been exemplified as an example of the substrate, the present disclosure is not limited thereto, and various other substrates may be used.

According to an aspect, it is possible to embed an insulating film in a desired shape by using a flowable film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

The above-described embodiments include, for example, the following aspects.

(Appendix 1) A method of forming an insulating film on a substrate having a recess, the method including process of: (O) preparing the substrate in a chamber of a processing apparatus; (A) forming a flowable oligomer film on the substrate by supplying a processing gas containing a raw material gas and a diluent gas into the chamber and generating a flowable oligomer by plasma polymerization; (B) controlling the interior of the chamber to have a pressure equal to or lower than the vapor pressure of the flowable oligomer to partially vaporize and remove the flowable oligomer film; and (C) forming the insulating film in the recess by supplying energy to the substrate to cure the flowable oligomer.
(Appendix 2) The method of appendix 1, wherein, in the process (B), the flowable oligomer film is vaporized by controlling the pressure inside the chamber to a second pressure lower than a first pressure controlled in the process (A) while stopping the processing gas.
(Appendix 3) The method of appendix 1 or 2, wherein, in the process (B), the flowable oligomer film is vaporized by controlling a substrate temperature to a second substrate temperature higher than a first substrate temperature controlled in the process (A) while stopping the processing gas.
(Appendix 4) The method of appendix 1 or 3, wherein, in the process (B), the flowable oligomer film is vaporized by controlling supply and stop of the diluent gas to be alternately repeated one or more times.
(Appendix 5) The method of appendix 1 or 3, wherein, in the process (B), the flowable oligomer film is vaporized by stopping the raw material gas while maintaining a flow rate and a pressure of the diluent gas supplied in the process (A).
(Appendix 6) The method of any one of appendices 1 to 5, further including (D) promoting fluidity of the flowable oligomer film by supplying a high vapor pressure gas after the process (A) and before the process (B).
(Appendix 7) The method of appendix 6, wherein, in the process (D), control is performed to raise a partial pressure of the raw material gas to be higher than in the process (B).
(Appendix 8) The method of appendix 7, wherein, in the process (D), the pressure inside the chamber is controlled to a third pressure higher than the first pressure controlled in the process (A).
(Appendix 9) The method of any one of appendices 6 to 8, wherein the high vapor pressure gas supplied in the process (D) is a material having a vapor pressure equal to or lower than the vapor pressure of the raw material gas.
(Appendix 10) The method of any one of appendices 6 to 9, wherein the high vapor pressure gas is at least one of ethanol, IPA, acetone, or the raw material gas.
(Appendix 11) The method of any one of appendices 1 to 10, wherein the process (A) and the process (B) are performed in the same processing apparatus, and the process (B) and the process (C) are performed in separate process apparatuses, respectively.
(Appendix 12) The method of any one of appendices 1 to 11, wherein the process (A), the process (B), and the process (C) are performed in separate processing apparatuses, respectively.
(Appendix 13) The method of any one of appendices 1 to 12, wherein the process (A) and the process (B) are performed in separate processing apparatus, respectively, and the process (B) and the process (C) are performed in the same processing apparatus.
(Appendix 14) The method of any one of appendices 1 to 13, wherein the process (A), the process (B), and the process (C) are repeated in this order.
(Appendix 15) The method of any one of appendices 3 to 14, wherein the first substrate temperature controlled in the process (A) is controlled to be less than 50 degrees C., and the second substrate temperature controlled in the process (B) is controlled to be 50 degrees C. or higher.
(Appendix 16) The method of any one of appendices 3 to 15, wherein the process (A) is performed while the substrate is placed on a stage, and the process (B) is performed while the substrate is separated from the stage.
(Appendix 17) The method of any one of appendices 1 to 16, wherein, in the process (A), the flowable oligomer is formed by plasma polymerization by adding a non-oxidizing hydrogen-containing gas to the processing gas, and performing plasma processing.
(Appendix 18) The method of any one of appendices 1 to 17, wherein, in the process (C), the energy supplied to the substrate is at least one of thermal energy, plasma energy, or UV energy.
(Appendix 19) The method of any one of appendices 1 to 18, wherein, in the process (C), the substrate temperature is controlled to a temperature exceeding 100 degrees C.
(Appendix 20) The method of any one of appendices 1 to 19, wherein, in the process (C), the insulating film is formed by generating plasma containing a hydrogen-containing gas.
(Appendix 21) The method of any one of appendices 1 to 19, wherein, in the process (C), the insulating film is formed by generating plasma containing a gas containing carbon and hydrogen.
(Appendix 22) The method of any one of appendices 1 to 20, wherein the raw material gas is a silicon-containing gas or a boron-containing gas.
(Appendix 23) The method of appendix 22, wherein the silicon-containing gas is a gas containing a Si—O bond.
(Appendix 24) The method of appendix 23, wherein the gas containing the Si—O bond is at least one selected from tetramethoxysilane, methyltrimethoxysilane, tetraethoxysilane, methyltriethoxysilane, dimethyldimethoxysilane, triethoxysilane, trimethoxysilane, or trimethoxy disiloxane.
(Appendix 25) The method of appendix 22, wherein the silicon-containing gas is a gas containing a Si—N bond.
(Appendix 26) The method of appendix 25, wherein the gas containing the Si—N bond is at least one selected from bis(tert-butylamino)silane, bis(tert-butylamino)methylsilane, bis(ethylmethylamino)silane, tridimethylaminosilane, methyltridimethylaminosilane, and hexamethylcyclotrisilazane.
(Appendix 27) The method of appendix 22, wherein the boron-containing gas is at least one selected from diborane, borazine, triethylborane, triethylamineborane, tri(dimethylamino)borane, tri(ethylmethylamino)borane, or trimethylborazine.
(Appendix 28) The method of any one of appendices 1 to 27, wherein the flowable oligomer includes any of SiOH, SiNH, SiCOH, SiCNH, SiCH, BNH, BCNH, SiBCNH, and SiBNH as a basic structure.
(Appendix 29) The method of any one of appendices 1 to 28, wherein the insulating film includes any of SiO₂, SiN, SiOC, SiCN, SiC, BN, BCN, SiBCN, and SiBN.
(Appendix 30) The method of appendix 29, wherein the insulating film includes a high-k film or a metal-containing film containing any of the elements: tin (Sn), aluminum (Al), hafnium (Hf), and zirconium (Zr).
(Appendix 31) The method of any one of appendices 1 to 30, wherein the diluent gas is at least one selected from an inert gas, H₂ gas, halogen gas, or hydrocarbon gas.
(Appendix 32) A substrate processing system including: a plurality of processing apparatuses configured to process a substrate having a recess; a transfer mechanism configured to transfer the substrate among the plurality of processing apparatuses, and a controller configured to execute a process, wherein the process includes processes of: (O) transferring the substrate to any of the plurality of processing apparatuses by the transfer mechanism; (A) forming a flowable oligomer film on the substrate by supplying a processing gas containing a raw material gas and a diluent gas into the chamber and generating a flowable oligomer by plasma polymerization; (B) controlling an interior of the chamber to have a pressure equal to or lower than a vapor pressure of the flowable oligomer to partially vaporize and remove the flowable oligomer film; and (C) forming an insulating film in the recess by supplying energy to the substrate to cure the flowable oligomer.

What is claimed is:

1. A method of forming an insulating film on a substrate having a recess, the method comprising:
preparing the substrate inside a chamber of a processing apparatus;
forming a flowable oligomer film on the substrate by supplying a processing gas containing a raw material gas and a diluent gas into the chamber and generating a flowable oligomer by plasma polymerization;
controlling an interior of the chamber to have a pressure equal to or lower than a vapor pressure of the flowable oligomer to partially vaporize and remove the flowable oligomer film; and
forming the insulating film in the recess by supplying energy to the substrate to cure the flowable oligomer.

2. The method of claim 1, wherein, in the controlling an interior of the chamber, the flowable oligomer film is vaporized by controlling the pressure inside the chamber to a second pressure lower than a first pressure controlled in the forming a flowable oligomer film while stopping the processing gas.

3. The method of claim 1, wherein, in the controlling an interior of the chamber, the flowable oligomer film is vaporized by controlling a substrate temperature to a second substrate temperature higher than a first substrate temperature controlled in the forming a flowable oligomer film while stopping the processing gas.

4. The method of claim 1, wherein, in the controlling an interior of the chamber, the flowable oligomer film is vaporized by controlling supply and stop of the diluent gas to be alternately repeated one or more times.

5. The method of claim 1, wherein, in the controlling an interior of the chamber, the flowable oligomer film is vaporized by stopping the raw material gas while maintaining a flow rate and a pressure of the diluent gas supplied in the forming a flowable oligomer film.

6. The method of claim 1, further comprising:
promoting fluidity of the flowable oligomer film by supplying a high vapor pressure gas after the forming a flowable oligomer film and before the controlling an interior of the chamber.

7. The method of claim 6, wherein, in the promoting fluidity, control is performed to raise a partial pressure of the raw material gas to be higher than in the controlling an interior of the chamber.

8. The method of claim 7, wherein, in the promoting fluidity, the pressure inside the chamber is controlled to a third pressure higher than a first pressure controlled in the forming a flowable oligomer film.

9. The method of claim 6, wherein the high vapor pressure gas supplied in the promoting fluidity is a material having a vapor pressure equal to or lower than the vapor pressure of the raw material gas.

10. The method of claim 6, wherein the high vapor pressure gas is at least one of ethanol, IPA, acetone, or the raw material gas.

11. The method of claim 1, wherein the forming a flowable oligomer film and the controlling an interior of the chamber are performed in a same processing apparatus, and
the controlling an interior of the chamber and the forming the insulating film are performed in separate processing apparatuses, respectively.

12. The method of claim 1, wherein the forming a flowable oligomer film, the controlling an interior of the chamber, and the forming the insulating film are performed in separate processing apparatuses, respectively.

13. The method of claim 1, wherein the forming a flowable oligomer film and the controlling an interior of the chamber are performed in separate processing apparatus, respectively, and the controlling an interior of the chamber and the forming the insulating film are performed in a same processing apparatus.

14. The method of claim 1, wherein the forming a flowable oligomer film, the controlling an interior of the chamber, and the forming the insulating film are repeated in this order.

15. The method of claim 3, wherein the first substrate temperature controlled in the forming a flowable oligomer film is controlled to be less than 50 degrees C., and the second substrate temperature controlled in the controlling an interior of the chamber is controlled to be 50 degrees C. or higher.

16. The method of claim 3, wherein the forming a flowable oligomer film is performed while the substrate is placed on a stage, and the controlling an interior of the chamber is performed while the substrate is separated from the stage.

17. The method of claim 1, wherein, in the forming a flowable oligomer film, the flowable oligomer is generated by plasma polymerization by adding a non-oxidizing hydrogen-containing gas to the processing gas, and performing plasma processing.

18. The method of claim 1, wherein, in the forming the insulating film, the energy supplied to the substrate is at least one of thermal energy, plasma energy, or UV energy.

19. The method of claim 1, wherein, in the forming the insulating film, a substrate temperature is controlled to a temperature exceeding 100 degrees C.

20. The method of claim 1, wherein, in the forming the insulating film, the insulating film is formed by generating plasma containing a hydrogen-containing gas.

21. The method of claim 1, wherein, in the forming the insulating film, the insulating film is formed by generating plasma containing a gas containing carbon and hydrogen.

22. The method of claim 1, wherein, the raw material gas is a silicon-containing gas or a boron-containing gas.

23. The method of claim 22, wherein the silicon-containing gas is a gas containing a Si—O bond.

24. The method of claim 23, wherein the gas containing the Si—O bond is at least one selected from tetramethoxysilane, methyltrimethoxysilane, tetraethoxysilane, methyltriethoxysilane, dimethyldimethoxysilane, triethoxysilane, trimethoxysilane, or trimethoxy disiloxane.

25. The method of claim 22, wherein the silicon-containing gas is a gas containing a Si—N bond.

26. The method of claim 25, wherein the gas containing the Si—N bond is at least one selected from bis(tert-butylamino)silane, bis(tert-butylamino)methylsilane, bis(ethylmethylamino)silane, tridimethylaminosilane, methyltridimethylaminosilane, and hexamethylcyclotrisilazane.

27. The method of claim 22, wherein the boron-containing gas is at least one selected from diborane, borazine, triethylborane, triethylamineborane, tri(dimethylamino)borane, tri(ethylmethylamino)borane, or trimethylborazine.

28. The method of claim 1, wherein the flowable oligomer comprises any of SiOH, SiNH, SiCOH, SiCNH, SiCH, BNH, BCNH, SiBCNH, and SiBNH as a basic structure.

29. The method of claim 1, wherein the insulating film includes any of SiO₂, SiN, SiOC, SiCN, SiC, BN, BCN, SiBCN, and SiBN.

30. The method of claim 29, wherein the insulating film includes a high-k film or a metal-containing film containing any of elements: tin (Sn), aluminum (Al), hafnium (Hf), and zirconium (Zr).

31. The method of claim 1, wherein the diluent gas is at least one selected from an inert gas, H₂ gas, halogen gas, or hydrocarbon gas.

32. A substrate processing system comprising:
a plurality of processing apparatuses configured to process a substrate having a recess;
a transfer mechanism configured to transfer the substrate among the plurality of processing apparatuses; and
a controller configured to execute a process,
wherein the process comprises:
transferring the substrate to any of the plurality of processing apparatuses by the transfer mechanism;
forming a flowable oligomer film on the substrate by supplying a processing gas containing a raw material gas and a diluent gas into the chamber and generating a flowable oligomer by plasma polymerization;
controlling the interior of the chamber to have a pressure equal to or lower than the vapor pressure of the flowable oligomer to partially vaporize and remove the flowable oligomer film; and
forming an insulating film in the recess by supplying energy to the substrate to cure the flowable oligomer.
